(19) United States
(12) Patent Application Publication
(10) Pub. No.: US 2019/0242941 A1
(43) Pub. Date: Aug. 8, 2019

(54) Methods and Apparatus for Testing an Integrated Circuit

(71) Applicant: Marvell World Trade Ltd., St. Michael (BB)

(72) Inventors: Scott Wu, San Jose, CA (US); Marc Jacobs, Redwood City, CA (US); Vincent Chun Kui Ng, San Francisco, CA (US); Ming Chang Liu, Fremont, CA (US)

(73) Assignee: Marvell World Trade Ltd., St. Michael (BB)

(21) Appl. No.: 16/169,552

(22) Filed: Oct. 24, 2018

Related U.S. Application Data
(60) Provisional application No. 62/627,113, filed on Feb. 6, 2018.

(51) Int. Cl. G01R 31/28; G01R 31/319

(52) U.S. Cl. CPC G01R 31/2886; G01R 31/31905; G01R 31/2863

(57) ABSTRACT

The present disclosure describes methods and apparatuses for testing an integrated circuit. In some aspects, a test engine of a system-on-chip (SoC) receives a test trigger from an external test port of a multi-chip module. The multi-chip module includes the SoC and integrated circuitry. Responsive to receiving the test trigger, the test engine initiates execution of a test associated with the integrated circuitry. The test engine also generates test data associated with the test and provides the test data at the external test port of the MCM. In this manner, internal tests can be executed within the multi-chip module. In other aspects, the SoC and the integrated circuitry are not packaged together. The test engine can receive the test trigger from a test port of the SoC and initiate execution of the test. In this way, the SoC may act as a test instrument for the integrated circuitry.

### CROSS REFERENCE TO RELATED APPLICATION

This present disclosure claims priority to U.S. Provisional Patent Application Ser. No. 62/627,113 filed Feb. 6, 2018, the disclosure of which is incorporated by reference herein in its entirety.

### BACKGROUND

Computing and electronic devices are often implemented with integrated circuits. One or more of these integrated circuits may be integrated within a package, such as a multi-chip module (MCM) or a system-in-package (SiP), within the device. Prior to packaging, an unpackaged integrated circuit may undergo testing and be labeled as a “known good die” (KGD) based on its performance.

During the packaging process, however, the integrated circuit can become damaged or connections between the integrated circuit and other components within the package can break. Once in the package, however, it can be challenging to test the integrated circuit and these internal interfaces. If the package does support internal testing, these problems may not be discovered until the device is tested in the field or sold to a customer. It may also be difficult to determine the cause of the problem once the components are integrated within the package.

### SUMMARY

This summary is provided to introduce subject matter that is further described in the Detailed Description and Drawings. Accordingly, this Summary should not be considered to describe essential features nor used to limit the scope of the claimed subject matter.

In some aspects, a method is implemented by a test engine of a system-on-chip (SoC) that is integrated within a multi-chip module (MCM). The test engine receives a test trigger from an external test port of the MCM. The test engine then initiates execution of a test associated with integrated circuitry within the MCM responsive to the receiving of the test trigger. The test engine also generates test data associated with the test and provides the test data at the external test port of the MCM.

In other aspects, a multi-chip module (MCM) comprises an external test port, integrated circuitry, and a system-on-chip (SoC). The SoC is coupled to the external test port and the integrated circuitry. The SoC includes a test engine configured to receive a test trigger from the external test port of the MCM. The test engine then initiates execution of a test associated with the integrated circuitry responsive to the receiving of the test trigger. The test engine also generates test data associated with the test and provides the test data at the external test port of the MCM.

In yet other aspects, a System-on-Chip comprises a test port, at least one interface node, and a test engine. The at least one interface node is configured to connect to integrated circuitry via an interface. The test engine is coupled to the test port and the at least one interface node. The test engine is configured to receive a test trigger via the test port. The test engine then initiates execution of a test associated with the integrated circuitry via the interface node responsive to the receiving of the test trigger.

The details of one or more implementations are set forth in the accompanying drawings and the following description. Other features and advantages will be apparent from the description and drawings, and from the claims.

### BRIEF DESCRIPTION OF THE DRAWINGS

The details of one or more implementations of testing an integrated circuit are set forth in the accompanying figures and the detailed description below. In the figures, the left-most digit of a reference number identifies the figure in which the reference number first appears. The use of the same reference numbers in different instances in the description and the figures indicates like elements:

FIG. 1 illustrates an example operating environment that includes a multi-chip module implemented in accordance with one or more aspects.

FIG. 2 illustrates example implementations of a system-on-chip and integrated circuitry for testing an integrated circuit.

FIG. 3 illustrates an example multi-chip module in which devices of the example environment can initiate internal tests.

FIG. 4 illustrates another example multi-chip module in which devices of the example environment can initiate internal tests.

FIG. 5 illustrates example signals that propagate between a system-on-chip and a memory integrated circuit during a memory loopback test.

FIG. 6 illustrates an example method for testing an integrated circuit.

FIG. 7 illustrates an example System-on-Chip (SoC) environment for implementing aspects of testing an integrated circuit.

### DETAILED DESCRIPTION

Conventional techniques for integrated circuit testing may be inaccessible if a die is integrated within a package, such as a multi-chip module (MCM) or a system-in-package (SiP). As such, reliance upon a “known good die” standard when integrating the die within the package without additional testing can cause problems to not be detected before field or system testing. A variety of different problems may occur within the package. For example, the die may become damaged or connections between the die and other components may become broken. The design of the package, however, can make it challenging to test the integrated circuit and these internal connections to detect and diagnose the problem prior to field or system testing.

To address at least this concern, this disclosure describes apparatuses and techniques for testing an integrated circuit. Generally, these apparatuses and techniques may use a test engine within a system-on-chip (SoC) to exercise one or more tests associated with integrated circuitry that is separate from the SoC. A test port on the SoC can be used to trigger execution of the one or more tests and pass along test data. In some implementations, the SoC and the integrated circuitry are packaged together within a multi-chip module. Using these techniques, the integrated circuitry and interfaces within the multi-chip module can be tested and problems can be identified and diagnosed prior to field testing or deployment of the packaged SoC.

The present disclosure describes methods and apparatuses for testing an integrated circuit. In some aspects, a test engine of a system-on-chip (SoC) receives a test trigger from an external test port of a multi-chip module. The multi-chip module includes the SoC and integrated circuitry. Responsive to receiving the test trigger, the test engine initiates execution of a test associated with the integrated circuitry. The test engine also generates test data associated with the test and provides the test data at the external test port of the MCM. In this manner, internal tests can ran within the multi-chip module. In other aspects, the SoC and the integrated circuitry are not packaged together. The test engine can receive the test trigger from a test port of the SoC and initiate execution of the test. In this way, the SoC acts as a test instrument for the integrated circuitry.

The following discussion describes an operating environment, techniques that may be employed in the operating environment, and a System-on-Chip (SoC) in which components of the operating environment can be embodied. In the context of the present disclosure, reference is made to the operating environment by way of example only.

Operating Environment

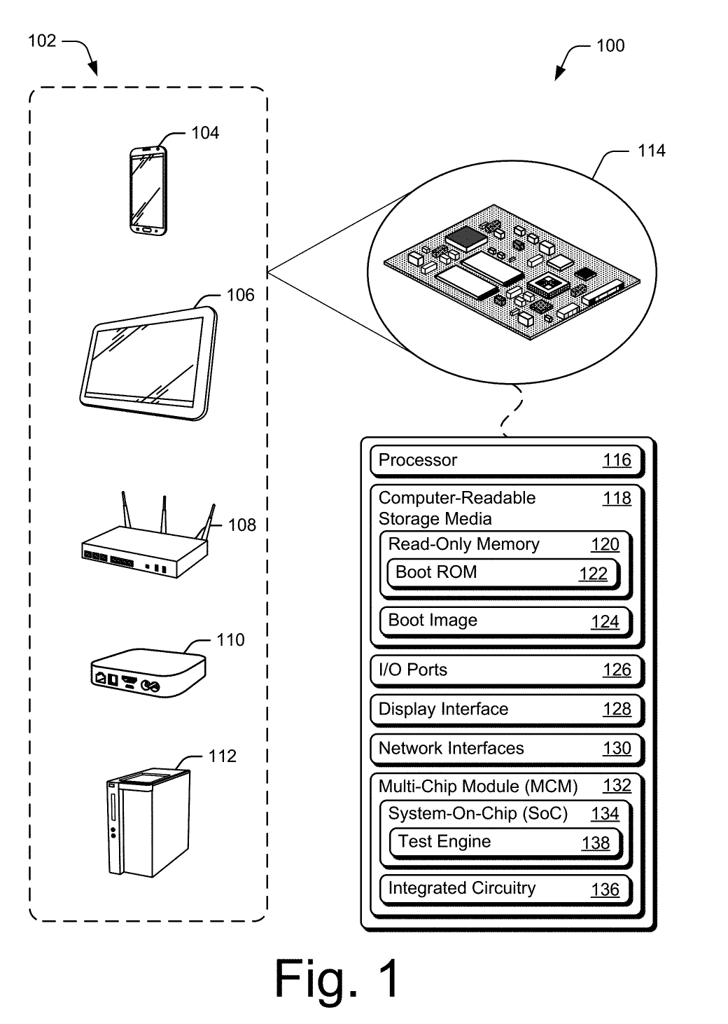

FIG. 1 illustrates an example operating environment 100 that includes an example computing device 102, which is capable of triggering execution of an internal test within a multi-chip module (MCM) in accordance with one or more aspects. Examples of the computing device 102 include a smart phone 104, a tablet computer 106, a wireless router 108, a set-top box 110, and a network-attached storage (NAS) device 112. Further examples of the computing device 102 include a desktop computer, a camera, a printer, a multimedia dongle, a personal media device, a navigation device, a portable gaming device, an Internet-of-Things (loT) device, and so on. The computing device 102 may initiate testing of the multi-chip module for any suitable purpose, such as to test an internal interface within the multi-chip module, test functionality of integrated circuitry within the multi-chip module, and the like.

The computing device 102 includes a printed circuit board assembly 114 (PCBA) 114 on which components and interconnects of the computing device are embodied. Alternately or additionally, components of the computing device 102 can be embodied on other substrates, such as flexible circuit material or other insulative material. Although not shown, the computing device 102 may also include a housing, various human-input devices, a display, a battery pack, antennas, and the like. Generally, electrical components and electromechanical components of the computing device 102 are assembled onto a printed circuit board (PCB) to form the PCBA 114. Various components of the PCBA 114 (e.g., processors and memories) are then programmed and tested to verify correct function of the PCBA. The PCBA 114 is connected to or assembled with other parts of the computing device 102 into a housing.

In this particular example, the PCBA 114 includes a processor 116 and computer-readable storage media 118. The processor 116 can be any suitable type of processor, either single core or multi-core, for executing instructions or commands of an operating system or application of the computing device 102. The computer-readable storage media 118 (CRM 118) includes volatile memory and non-volatile memory for storing various data and instructions of the computing device 102. In the context of this disclosure, the CRM 118 is implemented as storage media, and thus does not include transitory signals or carrier waves.

The CRM 118 includes a read-only memory 120 (ROM 120) storing boot ROM code 122 (Boot ROM 122), which can be executed at power-on to initialize components of the computing device 102. Alternately or additionally, the boot ROM 122 may program or configure components of the PCBA 114 during various stages of test and assembly. The CRM 118 also includes a boot image 124 to boot the computing device 102 and perform other functions, such as system initialization, component configuration, component testing, and the like. The implementations and uses of boot ROM 122 and boot image 124 vary and are described throughout the disclosure.

The PCBA 114 may also include I/O ports 126, display interface 128, and network interfaces 130. The I/O ports 126 allow the computing device 102 to interact with other devices or users. The I/O ports 126 may include any combination of internal or external ports, such as USB ports, audio ports, Serial ATA (SATA) ports, PCI-express based ports or card-slots, secure digital input/output (SDIO) slots, and/or other legacy ports. Various peripherals may be operatively coupled with the I/O ports 126, such as human-input devices (HIDs), external computer-readable storage media, or other peripherals.

The display interface 128 enables presentation of a user interface or other graphics of the computing device 102 via a display connected to the interface. The display may be integrated with the computing device 102 or an external display connected via a wired or wireless link. The network interfaces 130 provide connectivity to one or more networks and other devices connected therewith. Data communicated over network interfaces 130 may be packetized or framed depending on a communication protocol or standard by which the computing device 102 is communicating. The network interfaces 130 may include wired interfaces, such as Ethernet or fiber optic interfaces for communication over a local network, intranet, or the Internet. Alternately or additionally, the network interfaces 130 may include wireless interfaces that facilitate communication over wireless networks, such as wireless LANs, cellular networks, or wireless personal-area-networks (WPANs).

The computing device 102 or PCBA 114 also includes a multi-chip module (MCM)132. The MCM 132, which may also be considered a system-in-package (SiP) in some aspects, implements one or more functions within the computing device 102. Example functions can support wireless communications, networking, a user application, a security application, internal or external sensing, timing control, and so forth. The MCM 132 includes at least one system-on-chip (SoC) 134 and integrated circuitry 136. The integrated circuitry 136 can comprise one or more integrated circuits. The integrated circuit can be designed to perform logic operations, provide memory storage, provide power management, provide timing control, generate signals for communication, and so forth. In some cases, the integrated circuitry 136 comprises memory circuitry, which can provide additional memory storage for the SoC 134 or the computing device 102. The SoC 134 communicates with the integrated circuitry 136 and includes a test engine 138. Using the test engine 138, the SoC 134 can execute a variety of different tests within the MCM 132 to evaluate an interface between the SoC 134 and the integrated circuitry 136, or to evaluate the integrated circuitry 136. The implementations and uses of the SoC 134, the integrated circuitry 136, and the test engine 138 vary and are described throughout the disclosure.

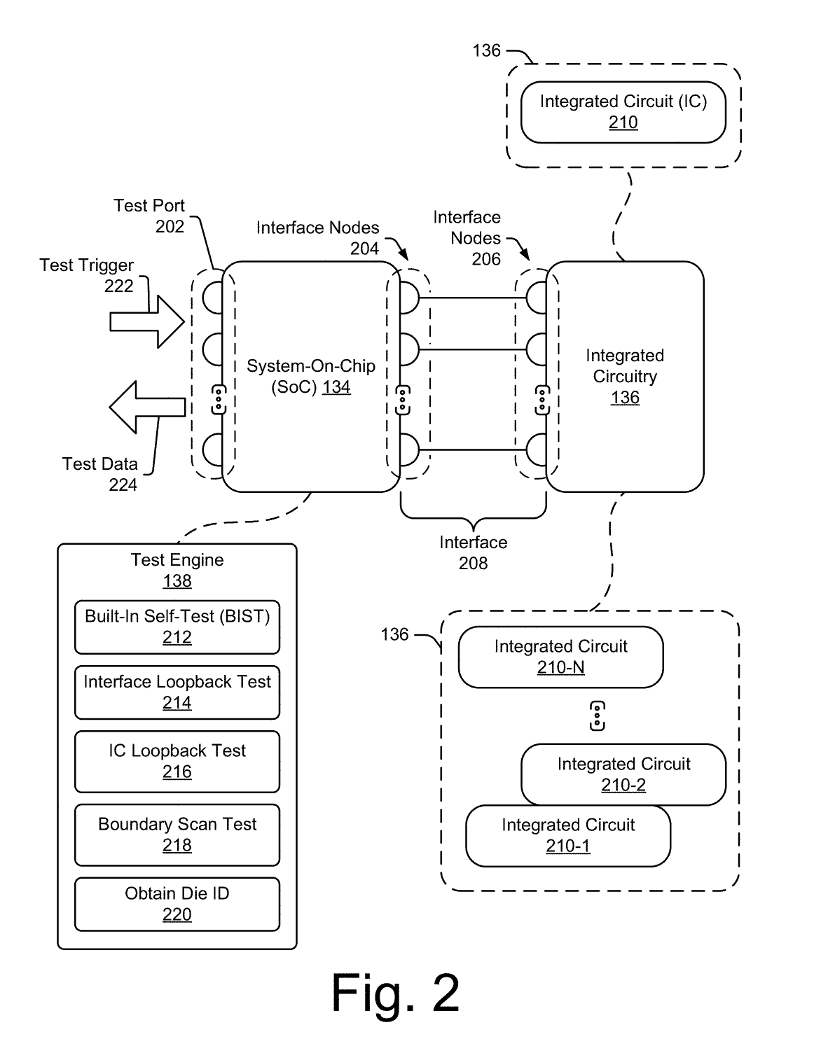

FIG. 2 illustrates example implementations of the SoC 134 and the integrated circuitry 136 for testing an integrated circuit. In the depicted configuration, the SoC 134 includes a test port 202 and one or more interface nodes 204 (e.g., pads or terminals). The test port 202 comprises one or more nodes and can be implemented as a Joint Test Action Group (JTAG) port. The interface nodes 204 are respectively coupled to interface nodes 206 of the integrated circuitry 136 via an interface 208. In some aspects, the interface 208 is implemented with wires, printed circuit board (PCB) traces, solder balls, vias, pins, sockets, interposer structures, or any suitable combination thereof. The interface 208 may also be associated with a particular bus standard, such as peripheral component interconnect express (PCIe).

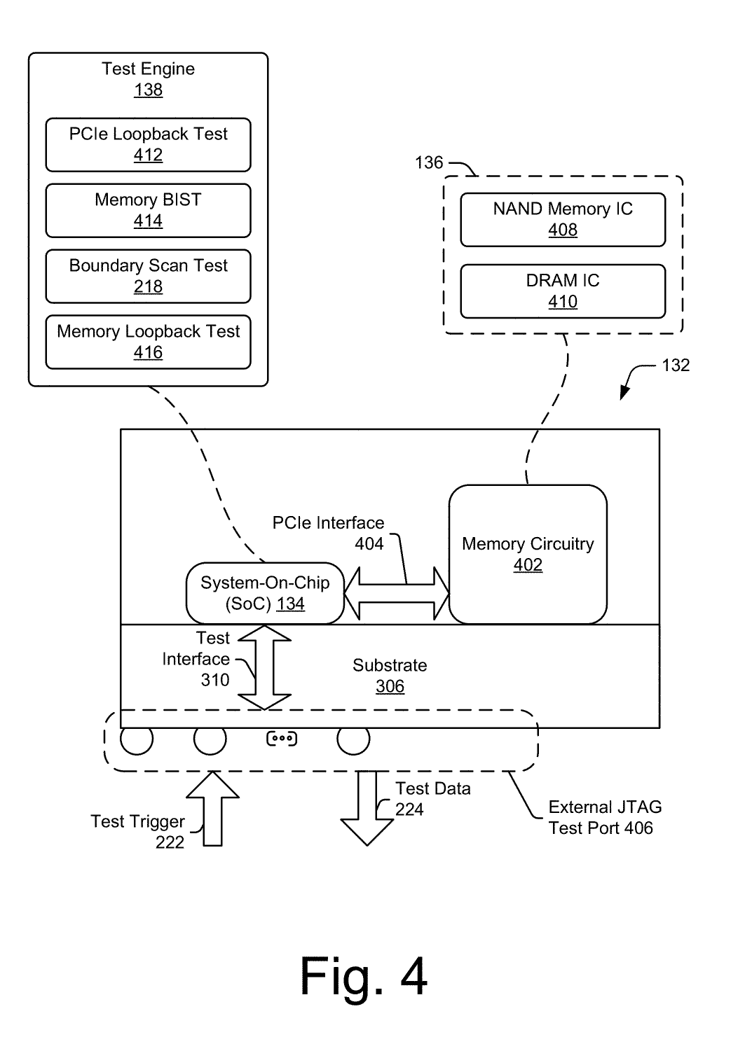

The integrated circuitry 136 includes at least one integrated circuit (IC) 210, as shown at the top of FIG. 2. In some implementations, the integrated circuitry 136 includes multiple integrated circuits 210-1 to 210-N, where N is a positive integer. At the bottom of FIG. 2, the multiple integrated circuits 210-1 to 210-N are shown to be stacked vertically. One or more of the integrated circuits 210-1 to 210-N can be connected together. In some aspects, the integrated circuitry 136 comprises memory circuitry having one or more memory integrated circuits, as further described with respect to FIG. 4.

The test engine 138 of the SoC 134 can initiate execution of a variety of different types of tests that can evaluate the interface 208, internal interfaces within the integrated circuitry 136, or functionality of or provided by the integrated circuitry 136. For example, the test engine 138 can initiate execution of a built-in self-test (BIST) 212 of the integrated circuitry 136, an interface loopback test 214 of the interface 208, an integrated circuit (IC) loopback test 216 associated with one or more of the integrated circuits 210-1 to 210-N, a boundary scan test 218 of the integrated circuitry 136, or so forth. The test engine 138 can also obtain a die identification of the one or more integrated circuits 210-1 to 210-N within the integrated circuitry 136. The die identification may be any unique number associated with an integrated circuit 210, such as a serial number of the integrated circuit burned into one-time programmable memory or other non-volatile memory.

Prior to initiating a test, the test engine 138 can appropriately configure the integrated circuitry 136 for the test. For example, the test engine 138 can cause the integrated circuitry 136 to be in a stand-by state during the test to avoid bus contention over the interface 208. In the stand-by state, the integrated circuitry 136 waits to receive signals across the interface 208. In other words, the integrated circuitry 136 does not actively send signals across the interface 208 unless prompted to do so by the test engine 138 for the test.

Generally, the test engine 138 can selectively be in an active state or an inactive state. In the active state, the test engine 138 can facilitate execution of one or more of the above tests. The test engine 138 can also generate test data associated with the test. For some tests, the test engine 138 can collect and compile results that are provided by the integrated circuitry 136. In some cases, the test engine 138 can analyze the test data to determine if the test results are indicative of a success or failure. With the obtain die identification function 220, the test engine 138 can also identify which integrated circuit 210-1 to 210-N passed or failed. The test data 224 can be provided to the processor 116 via the test port 202.

In the inactive state (e.g., idle state), the test engine 138 waits to receive a test trigger 222, which causes the test engine 138 to transition to the active state. The test engine 138 can receive the test trigger 222 via the test port 202. The test trigger 222 causes the test engine 138 to initiate execution of one or more of the above tests. In some cases, the test trigger 222 comprises source code or pseudo code that controls the test engine 138. In other cases, the test trigger 222 can be a change in voltage of a test mode signal that is provided at the test port 202. In some aspects, the processor 116 of the computing device 102 can provide or control the test trigger 222. The test trigger 222 can also identify which test is to be initiated by the test engine 138.

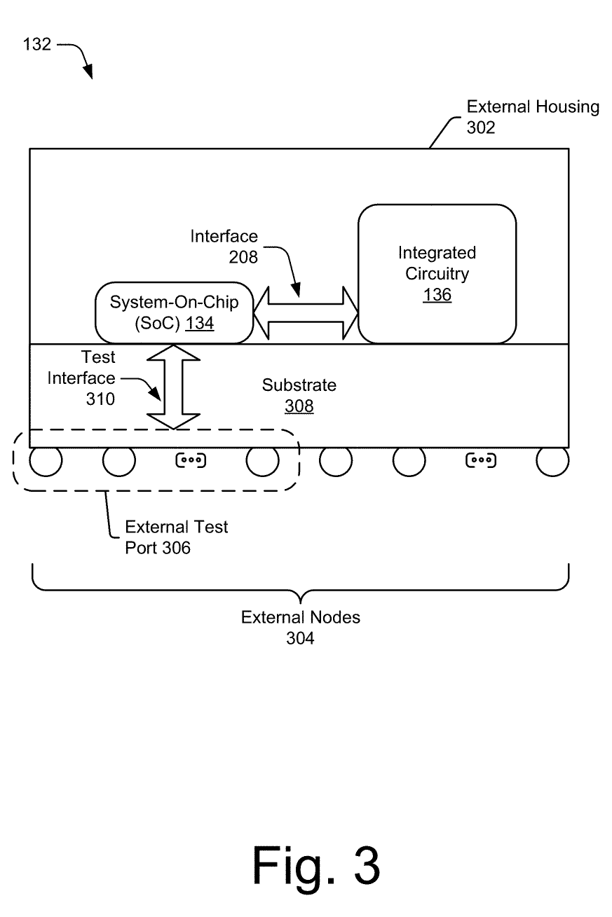

Although the SoC 134 and the integrated circuitry 136 are not packaged together in FIG. 2, the test engine 138 and the interface 208 can be used to test the integrated circuitry 136. In this case, the SoC 134 may function as a test instrument and initiate tests associated with the integrated circuitry 136. This also enables the testing to be performed prior to packaging the SoC 134 and the integrated circuitry 136 together, as further described with respect to FIG. 3.

FIG. 3 illustrates an example MCM 132 in which devices of the example environment 100 can initiate internal tests therein. In the depicted configuration, the MCM 132 includes an external housing 302 and one or more external nodes 304. The external nodes 304 can comprise solder balls or pins that connect to other components within the computing device 102, such as the processor 116. At least a portion of the external nodes 304 implement an external test port 306, such as an external JTAG port.

Within the external housing 302, the MCM 132 includes a substrate 308. The SoC 134 and the integrated circuitry 136 are disposed on a surface of the substrate 308. A test interface 310 couples the test port 202 of the SoC 134 (shown in FIG. 2) to the external test port 306 of the MCM 132 through the substrate 308. Using the test interface 310, the test trigger 222 (of FIG. 2) can be passed from the external test port 306 to the SoC 134. Likewise, the test data 224 (of FIG. 2) can be passed from the SoC 134 to the external test port 306 via the test interface 310. In this manner, the computing device 102 can initiate execution of internal tests within the MCM 132 and obtain the test data 224 to determine if any problems are present. In some implementations, the integrated circuitry 136 includes memory integrated circuitry, which is further described with respect to FIG. 4.

FIG. 4 illustrates another example MCM 132 in which devices of the example environment can initiate internal tests therein. In the depicted configuration, the integrated circuitry 136 and the interface 208 of FIG. 3 are respectively implemented as memory circuitry 402 and a PCIe interface 404 in FIG. 4. Additionally, the external test port 306 of FIG. 3 comprises an external JTAG test port 406 in FIG. 4. To test the PCIe interface 404, the test engine 138 can initiate execution of a PCIe loopback test 412.

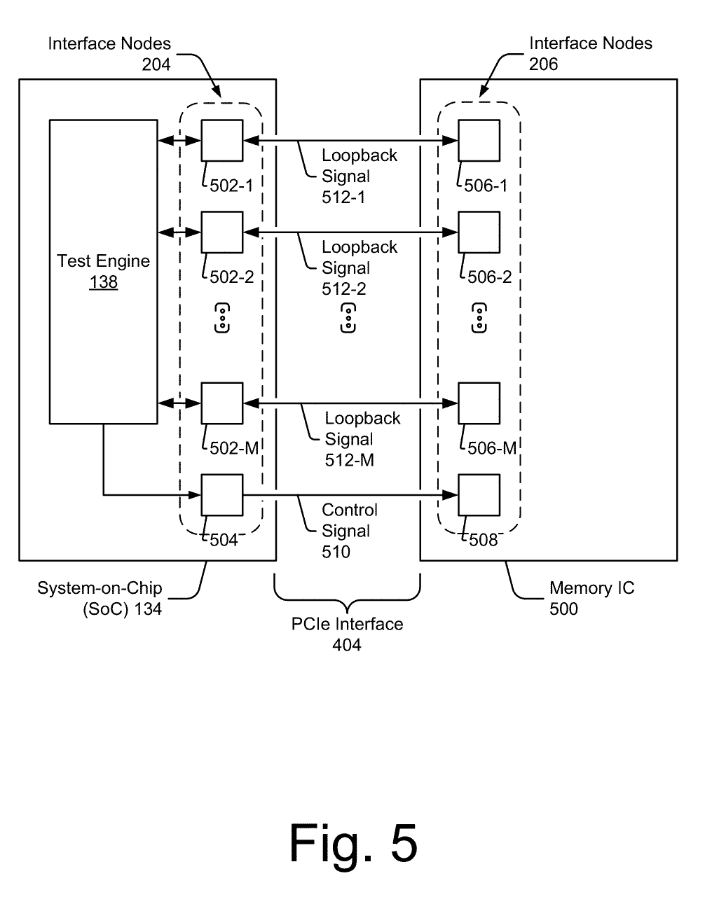

The memory circuitry 402 includes at least one memory integrated circuit, which can be implemented as a NAND memory integrated circuit 408 or a dynamic random-access memory (DRAM) memory integrated circuit 410. To test the memory circuitry 402, the test engine 138 can initiate execution of a memory built-in self-test (BIST) 412, the boundary scan test 218, or a memory loopback test 416. Prior to initiating the memory loopback test 416, the test engine 138 can place the memory circuitry 402 in a stand-by state or idle state, such as a write state, which is further described with respect to FIG. 5.

FIG. 5 illustrates example signals that propagate between the SoC 134 and a memory integrated circuit (IC) 500 of the memory circuitry 402 during the memory loopback test 416. In the depicted configuration, the interface nodes 204 of the SoC 134 include nodes 502-1 to 502-M and a control node 504. In this case, M represents a positive integer. The interface nodes 206 of the memory integrated circuit 500 includes the nodes 506-1 to 506-M and a state node 508.

Prior to initiating the memory loopback test 416, the test engine 138 sends a control signal 510 from the control node 504 to the state node 508. In this example, the control signal 510 causes the memory integrated circuit 500 to be in a write state to prevent the memory integrated circuit 500 from sending signals via the nodes 506-1 to 506-M without prompting from the test engine 138. In other words, the control signal 510 causes the input and output (10) of the memory integrated circuit 500 to be in a tri-state or a high-impedance state. In this state, contention over the PCIe interface 404 can be avoided during the memory loopback test 416. As such, the memory integrated circuit 500 is less likely to be damaged by the memory loopback test 416.

To initiate the memory loopback test 416, the test engine 138 can send loopback signals 512-1 to 512-M from the nodes 502-1 to 502-M to the nodes 506-1 to 506-M of the memory integrated circuit 500. Responsive to receiving the loopback signals 512-1 to 512-M, the memory integrated circuit 500 can send the loopback signals 512-1 to 512-M from the nodes 506-1 to 506-M back to the nodes 502-1 to 502-M of the SoC 134. The test engine 138 can then evaluate if the received loopback signals 512-1 to 512-M differ from the loopback signals that were previously sent. If the signals are similar, the test engine 138 can determine that memory integrated circuit 500 passed the memory loopback test 416. Alternatively if one or more of the signals differ, the test engine 138 can determine that the memory integrated circuit 500 failed the memory loopback test 416. In some cases, the test engine 138 can send another control signal 510 to the state node 508 to cause the memory integrated circuit 500 to transition to another state after the memory loopback test 416 is complete. As an example, the test engine 138 can cause the memory integrated circuit 500 to return to a previous state or a read state.

Technique of Testing an Integrated Circuit

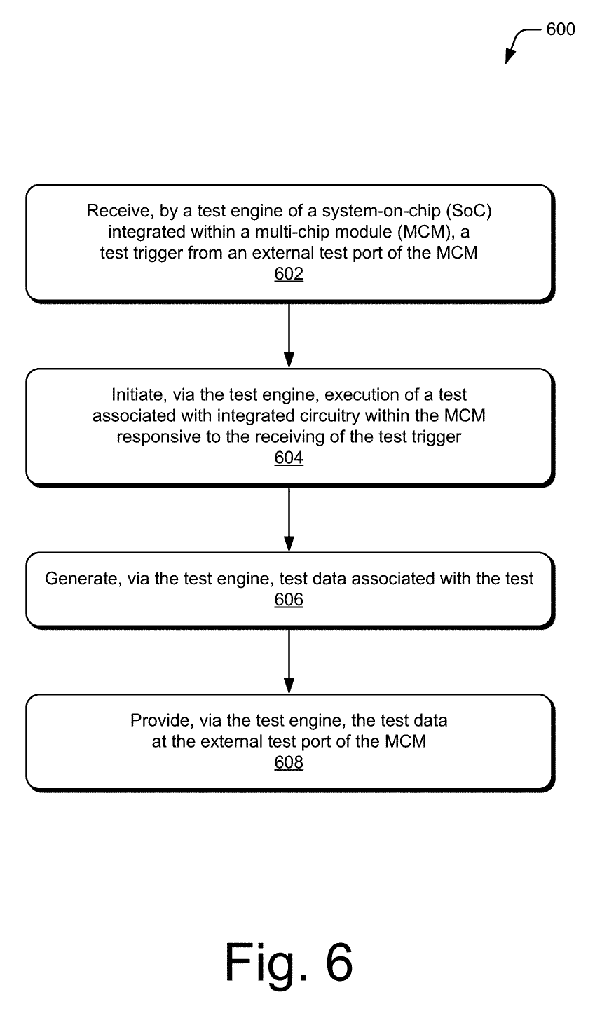

The following discussion describes techniques of testing an integrated circuit. These techniques can be implemented using any of the environments and entities described herein, such as the SoC 134 and the test engine 138. These techniques include a method illustrated in FIG. 6, which is shown as a set of operations performed by one or more entities. The method is not necessarily limited to the order of operations shown. Rather, any of the operations may be repeated, skipped, substituted, or re-ordered to implement various aspects described herein. Further, the method may be performed by the same entity, separate entities, or any combination thereof. In portions of the following discussion, reference will be made to operating environment 100 of FIG. 1 and entities of FIGS. 2 and 3 by way of example. Such reference is not to be taken as limiting described aspects to operating environment 100 but rather as illustrative of one of a variety of examples.

At 602, a test trigger is received by a test engine of a system-on-chip (SoC) integrated within a multi-chip module (MCM) from an external test port of the MCM. For example, the test engine 138 of the SoC 134, which is integrated within the MCM 132, receives the test trigger 222 from the external test port 306 of the MCM 132. The test trigger can comprise source code, pseudo code, or a test mode signal. In some aspects, the external test port 306 can comprise the external JTAG test port 406.

At 604, execution of a test associated with integrated circuitry within the MCM is initiated via the test engine responsive to the receiving of the test trigger. For example, the test engine 138 initiates execution of a test associated with the integrated circuitry 136 responsive to the receiving of the test trigger 222. A variety of different types of tests may be initiated as shown in FIGS. 2 and 4, including the built-in self-test (BIST) 212 of the integrated circuitry 136 (e.g., the memory BIST 414), the interface loopback test 214 of the interface 208 (e.g., the PCIe loopback test 412), the IC loopback test 216 (e.g., the memory loopback test 416), or the boundary scan test 218.

At 606, test data associated with the test is generated via the test engine. For example, the test engine 138 can generate the test data 224. The test data 224 can indicate whether or not a result of the test passed or failed. Sometimes the test data can associate the result with a die identification of the integrated circuit 210 within the integrated circuitry 136 that was tested. In some cases, the test engine can collect and compile results that are provided by the integrated circuitry 136.

At 608, the test data is provided at the external test port of the MCM via the test engine. For example, the test engine 138 provides the test data 224 at the external test port 306 of the MCM 132. The test data 224 can then be used to evaluate the internal interfaces and internal components within the MCM 132 and for diagnostics if a failure occurs. Thus, aspects of testing an integrated circuit may enable detection and diagnosis of any faults or failures of the internal circuitry prior to field testing or deployment of a packaged SoC.

System-on-Chip

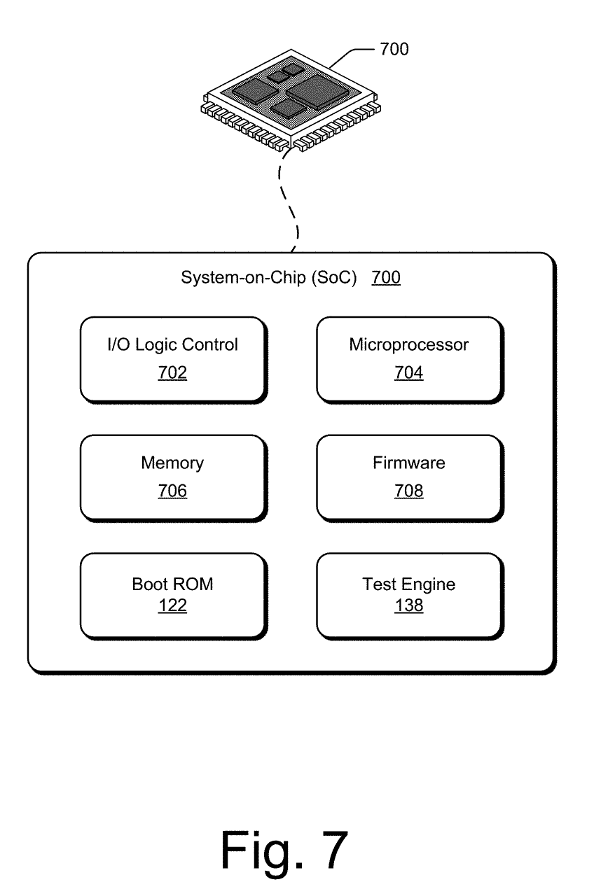

FIG. 7 illustrates an exemplary System-on-Chip (SoC) 700 that can implement various aspects of testing an integrated circuit. The SoC 700 can be implemented in any suitable device, such as a smart-phone, cellular phone, netbook, tablet computer, server, wireless router, network-attached storage, camera, smart appliance, printer, a set-top box, or any other suitable type of device. Although described with reference to a SoC, the entities of FIG. 7 may also be implemented as a system-in-package (SiP), application-specific standard part (ASSP), digital signal processor (DSP), programmable SoC (PSoC), or field-programmable gate array (FPGA).

The SoC 700 can be integrated with electronic circuitry, a microprocessor, memory, input-output (I/O) logic control, communication interfaces, other hardware, firmware, and/or software useful to provide functionalities of a device, such as any of the devices listed herein. The SoC 700 may also include an integrated data bus (not shown) that couples the various components of the SoC for data communication between the components. The integrated data bus or other components of the SoC 700 may be exposed or accessed through an external port, such as a JTAG port as described herein. For example, components of the SoC 700 may be tested, configured, or programmed (e.g., flashed) through the external port at different stages of manufacture.

In this example, the SoC 700 includes various components such as input-output (I/O) logic control 702 (e.g., to include electronic circuitry) and a microprocessor 704 (e.g., any of a microcontroller, processor core, application processor, or DSP). The SoC 700 also includes memory 706, which can be any type and/or combination of RAM, SRAM, DRAM, low-latency nonvolatile memory, ROM, one-time programmable (OTP) memory, and/or other suitable electronic data storage. In the context of this disclosure, the memory 706 stores data, instructions, or other information via non-transitory signals, and does not include carrier waves or other transitory signals.

Alternately or additionally, the SoC 700 may comprise a data interface (not shown) for accessing additional or expandable off-chip memory, such as external SRAM or flash memory. In some cases, the SoC 700 includes various applications, operating systems, and/or software, such as firmware 708 and boot ROM 122, which can be computer-executable instructions maintained by the memory 706 and executed by the microprocessor 704. The SoC 700 may also include other various memory interfaces and components embodied as hardware, firmware, software, or any suitable combination thereof.

The SoC 700 also includes a test engine 138, which may be embodied as a disparate entity or combined components, as described in relation to aspects presented herein. Examples of these components and/or entities, and their corresponding functionality, are described with reference to the respective components of the environment 100 shown in FIG. 1. The test engine 138, either in whole or part, can be implemented as processor-executable instructions (e.g., firmware 708) maintained by the memory 706 and executed by the microprocessor 704 to implement various aspects and/or features of testing an integrated circuit as described herein.

Although the subject matter has been described in language specific to structural features and/or methodological operations, it is to be understood that the subject matter defined in the appended claims is not necessarily limited to the specific features or operations described herein, including orders in which they are performed.

What is claimed is:

1. A method comprising:
receiving, by a test engine of a system-on-chip (SoC) integrated within a multi-chip module (MCM), a test trigger from an external test port of the multi-chip module (MCM);
initiating, via the test engine, execution of a test associated with integrated circuitry within the multi-chip module (MCM) responsive to the receiving of the test trigger;
generating, via the test engine, test data associated with the test; and
providing, via the test engine, the test data at the external test port of the multi-chip module (MCM).

2. The method as recited in claim 1, wherein the receiving of the test trigger comprises receiving the test trigger from an external Joint Test Action Group (JTAG) port of the multi-chip module (MCM).

3. The method as recited in claim 1, wherein the initiating execution of the test comprises initiating execution of at least one of the following tests:
a built-in self-test (GIST) of the integrated circuitry;
an interface loopback test associated with an interface between the SoC and the integrated circuitry;
an integrated circuit loopback test associated with an integrated circuit included within the integrated circuitry; or
a boundary scan test associated with the integrated circuitry.

4. The method as recited in claim 1, further comprising causing the integrated circuitry to be in a stand-by state prior to initiating execution of the test.

5. The method as recited in claim 4, wherein:
the integrated circuitry comprises memory circuitry, the memory circuitry including at least one memory integrated circuit; and
the causing of the integrated circuitry to be in the stand-by state comprises causing the memory integrated circuit to be in a write state prior to initiating execution of the test.

6. The method as recited in claim 1, further comprising:
obtaining a die identification of an integrated circuit included within the integrated circuitry; and
including the die identification within the test data.

7. The method as recited in claim 1, wherein the test data indicates whether a result of the test passed or failed.

8. A multi-chip module (MCM) comprising:
an external test port;
integrated circuitry; and
a system-on-chip (SoC) coupled to the external test port and the integrated circuitry, the SoC including a test engine configured to:
receive a test trigger from the external test port of the multi-chip module (MCM);
initiate execution of a test associated with the integrated circuitry responsive to the receiving of the test trigger;
generate test data associated with the test; and
provide the test data at the external test port of the multi-chip module (MCM).

9. The multi-chip module (MCM) as recited in claim 8, wherein:
the integrated circuitry includes at least one integrated circuit, the at least one integrated circuit is configured to execute a built-in self-test; and
the test engine is configured to cause the at least one integrated circuit to execute the built-in self-test responsive to the receiving of the test trigger.

10. The multi-chip module (MCM) as recited in claim 9, wherein the test engine is configured to:
obtain a die identification of the at least one integrated circuit; and
associate a result of the built-in self-test with the die identification within the test data.

11. The multi-chip module (MCM) as recited in claim 8, wherein:
the integrated circuitry includes at least one integrated circuit; and
the test engine is configured to initiate execution of a boundary scan test of the at least one integrated circuit responsive to the receiving of the test trigger.

12. The multi-chip module (MCM) as recited in claim 8, further comprising an interface between the SoC and the integrated circuitry,
wherein the test engine is configured to initiate execution of an interface loopback test associated with the interface.

13. The multi-chip module (MCM) as recited in claim 8, wherein:
the integrated circuitry comprises memory circuitry, the memory circuitry includes at least one memory integrated circuit, the at least one memory integrated circuit is configured to selectively be in a write state; and
the test engine is configured to:
cause the memory integrated circuit to be in the write state; and
initiate execution of a memory loopback test associated with the at least one memory integrated circuit after causing the memory integrated circuit to be in the write state.

14. The multi-chip module (MCM) as recited in claim 13, wherein the at least one memory integrated circuit comprises a NAND memory integrated circuit or a dynamic random-access memory (DRAM) integrated circuit.

15. The multi-chip module (MCM) as recited in claim 8, wherein the external test port comprises a Joint Action Test Group (JTAG) test port.

16. A System-on-Chip (SoC) comprising:
a test port;
at least one interface node configured to connect to integrated circuitry via an interface; and
a test engine coupled to the test port and the at least one interface node, the test engine configured to:
receive a test trigger via the test port; and
initiate execution of a test associated with the integrated circuitry via the interface node responsive to the receiving of the test trigger.

17. The SoC as recited in claim 16, wherein:
the integrated circuitry comprises memory circuitry, the memory circuitry includes at least one memory integrated circuit; and
the test engine is configured to:
cause the memory integrated circuit to be in a write state; and
initiate execution of a memory loopback test associated with the at least one memory integrated circuit after causing the memory integrated circuit to be in the write state.

18. The SoC as recited in claim 16, wherein the test engine is configured to execute at least one of the following tests responsive to the receiving of the test trigger:
a built-in self-test of the integrated circuitry;
an interface loopback test associated with the interface;
an integrated circuit loopback test associated with an integrated circuit of the integrated circuitry; or a boundary scan test associated with the integrated circuitry.

19. The SoC as recited in claim 16, wherein the test engine is configured to provide test data at the test port responsive to the execution of the test, the test data indicating whether a result of the test passed or failed.

20. The SoC as recited in claim 19, wherein:
the integrated circuitry includes at least one integrated circuit, the at least one integrated circuit having a die identification; and
the test engine is configured to:
obtain the die identification of the at least one integrated circuit; and
associate the result of the test with the die identification in the test data.
